(19) United States
(12) Patent Application Publication
(10) Pub. No.: US 2011/0031887 A1
(43) Pub. Date: Feb. 10, 2011

(54) LED LIGHTING SYSTEM

(76) Inventors: Arnold Stoll, Kitchener (CA); Paul von Zittwitz, Macomb, MI (US)

Correspondence Address: Patent Legal Counsel, PLLC, 2564 N. Squirrel Rd., #223, Aurburn Hills, MI, 48326, US

(21) Appl. No.: 12/790,745

(22) Filed: May 28, 2010

Related U.S. Application Data
(60) Provisional application No. 61/181,698, filed on May 28, 2009.
(60) Provisional application No. 61/307,837, filed on Feb. 24, 2010.

(51) Int. Cl. H01J 13/32; H05K 13/00

(52) U.S. Cl. 315/113; 29/592.1

(57) ABSTRACT

An illumination apparatus includes a LED assembly having a plurality of LED modules and a substrate. Each LED module includes an anode and a cathode. The substrate is generally planar and defined by a first side and a second side with the LED modules extending from the first side. The second side is defined by a heat dissipation surface, and wherein the first side is opposite the second side. The apparatus also includes a heat sink having a plurality of fins for heat dissipation. A heat input surface portion of the heat sink is bonded to the heat dissipation surface of the LED assembly. The apparatus further includes a control system for supplying electrical energy to the LED assembly, wherein the electrical energy is pulse width modulated.

### CROSS REFERENCE TO RELATED APPLICATIONS

This application claims priority to U.S. Provisional Applications 61/181,698, filed in the United States Patent and Trademark Office on the 28th day of May, 2009, and 61/307,837, filed in the United States Patent and Trademark Office on the 24th day of Feb., 2010, the disclosures of which are incorporated by reference in their entirety.

### TECHNICAL FIELD

The disclosure relates generally to Light Emitting Diode (“LED”) lighting systems and more particularly to an LED lighting system having improved heat dissipation characteristics.

### BACKGROUND

Standard filament bulb flashlight systems dissipate heat by radiating a large percentage of heat to the front lens and a smaller amount to the interior of the flashlight. The heat radiated to the front of the lens is dissipated to the environment. Such conventional heat dissipation systems are suitable for standard filament bulb systems and conventional low power light emitting diode (“LED”) flashlight systems. In other words, current low power LED flashlights have not required a special heat dissipation design.

Relatively high power LED lighting systems have recently become available. These higher power LED lighting systems (e.g., flashlights) dissipate heat by a different heat transfer path than ordinary filament bulb systems. More specifically, these higher power LED lighting systems dissipate a substantial amount of heat via a cathode (negative terminal) leg or through a die attached in a direct die mount device. Therefore, the conventional heat dissipation systems do not adequately reduce heat in higher power LED systems (e.g., flashlights). Consequently, the higher power LED systems tend to run at higher operating temperatures.

Higher operating temperatures degrade the performance of the high power LED lighting systems. Experiments with a wide variety of LEDs have suggested an exponential relationship of the life expectancy of an LED versus operating temperature. While ambient room temperature 25° C. (77° F.)) lifetimes may approach one hundred thousand hours, operation in an ambient environment of 90° C. 194° F.) may reduce an LED life to less than seven thousand hours.

The use of LEDs for lighting in instances such as a warehouse or other commercial venue may represent a significant cost savings compared to standard filament bulb lighting systems. However, the aforementioned problems in regards to heat dissipation significantly impact the availability of lighting for warehouses or commercial venues for high bay type lighting applications.

Accordingly, a need exists for an LED with improved heat dissipation characteristics, and more specifically, for an LED with improved heat dissipation characteristics for application as high bay lighting.

### SUMMARY

The drawings are illustrative embodiments. The drawings are not necessarily to scale and certain features may be removed, exaggerated, moved, or partially sectioned for clearer illustration.

Therefore, it is an object of the invention to provide an LED with improved heat dissipation characteristics.

It is an object of the invention to provide an LED with improved heat dissipation characteristics for use in a high bay lighting situation.

It is an object of the invention to provide an LED with improved heat dissipation characteristics for use in a high bay lighting situation having pleasing aesthetics.

It is an object of the invention to provide an LED with improved heat dissipation characteristics for use in a high bay lighting situation that is cost efficient to manufacture.

These and other embodiments of the present invention are provided within a light comprising a light emitting diode encased within a housing forming a heat sink, a power supply in electrical communication with the light emitting diode, and a control system for applying a pulse width modulating sequence to the power supply for varying the power supplied to the light emitting diode.

According to another embodiment of the invention, the light further includes a fixture having a bracket for being suspended from an elevated position.

According to another embodiment of the invention, the fixture includes a plurality of louvers rotatably attached to a surface of the fixture having an opening therein and positioned in proximity to the light emitting diode for allowing light to pass therethrough.

According to another embodiment of the invention, the housing has a plurality of sink fans for dissipating heat.

According to another embodiment of the invention, the light includes a fan positioned in proximity to the heat sink for dissipating heat.

According to another preferred embodiment of the invention, a light assembly is provided that includes at least one light emitting diode, a housing surrounding the light emitting diode, a heat sink integrally formed with the housing, and a fixture that houses the light emitting diode, the fixture including means for housing the light emitting diode and a plurality of rotatably attached louvers suspended from the fixture

According to another embodiment of the invention, the light assembly further includes a control system for varying incoming power to the light emitting diode.

According to another embodiment of the invention, the control system includes a pulse width modulator.

### BRIEF DESCRIPTION OF THE DRAWINGS

The drawings are illustrative embodiments. The drawings are not necessarily to scale and certain features may be removed, exaggerated, moved, or partially sectioned for clearer illustration. The embodiments illustrated herein are not intended to limit or restrict the claims.

FIG. 1 is schematic view of an illumination device, according to an embodiment.

FIG. 2 is detailed schematic view of a control system according to an embodiment.

FIG. 2A is detailed schematic view of a control system according to another embodiment.

FIG. 3 illustrates an embodiment of the device of FIG. 1.

FIG. 4 is an exploded view of the device of FIG. 3.

FIG. 5 is a top view of a heat sink, according to an embodiment.

FIG. 6 is an exploded view of the heat sink of FIG. 5 with a LED assembly.

FIG. 7 is a perspective view of the LED assembly of FIG. 6.

FIG. 8 is an exploded view taken along line 8-8 of FIG. 7.

FIG. 9 illustrates an embodiment of a circuit for the LED assembly of FIG. 6.

FIG. 10 is a perspective view of a heat sink, according to an embodiment.

FIG. 11 is a top view of the heat sink of FIG. 10.

FIG. 12 is a view taken along line 12-12 of FIG. 11.

FIG. 13 is a logic flow of a control scheme of a heat sensor, according to an embodiment.

FIG. 14 is a logic flow of a control scheme of a heat sensor, according to another embodiment.

FIG. 15 is a graphical illustration of differing control uses of the system of FIG. 2A.

FIG. 16 is a graphical illustration of another control use of the system of FIG. 2A.

FIG. 17 illustrates another embodiment of the device of FIG. 1.

FIG. 18 is a view taken generally along line 18-18 of FIG. 17.

### DETAILED DESCRIPTION

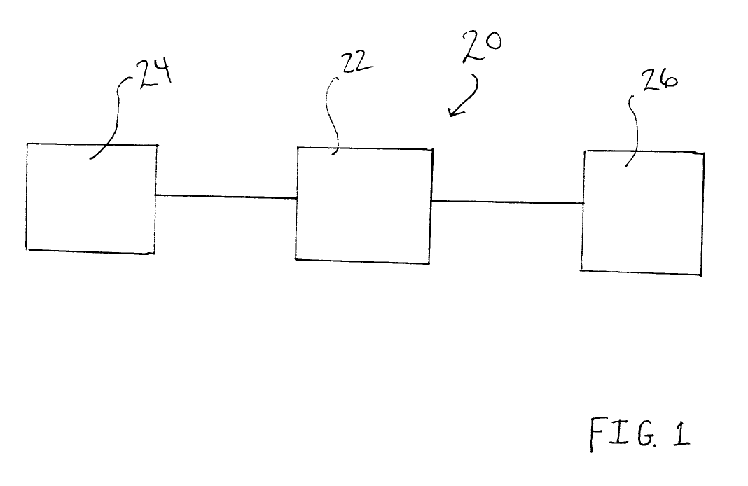

FIG. 1 illustrates an embodiment of an illumination device 20. The device 20 includes a control system 22, a power source 24, and a LED assembly 26. Generally, the control system 22 controls the transfer of electrical energy from the power source 24 to the LED assembly 26 while monitoring the LED assembly 26. In the embodiment illustrated, the power source 24 is electrical alternating current (AC), as discussed in greater detail below.

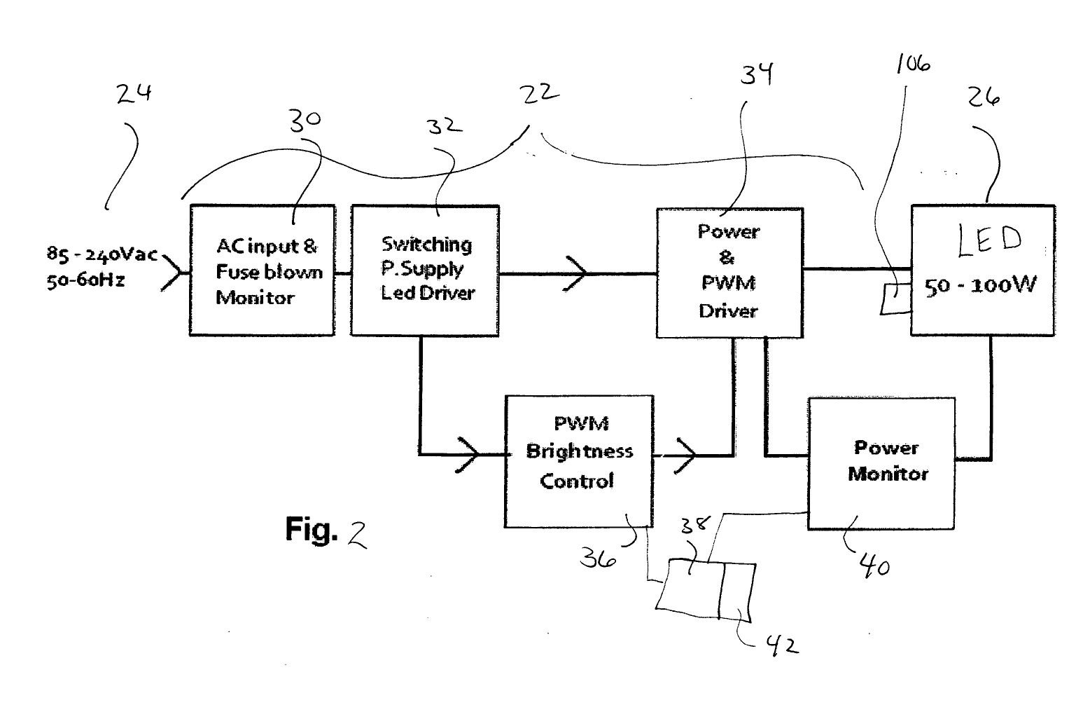

FIG. 2 illustrates an embodiment of the control system 22 to include an AC input protection 30, a LED Driver 32, a PWM driver 34, a brightness control 36, a user input 38, a power monitor 40, and a display 42.

FIG. 2A illustrates another embodiment of the control system 22 using a modular system. In this embodiment, the control system includes a first control module 44 and a temperature control module 46. The first control module 44 includes a first sensor 48, as discussed in greater detail below. In the embodiment of FIG. 2A, the power source 24 includes the PWM driver 34 for adjustably supplying current to the LED assembly 26 in a pulse-width modulated fashion.

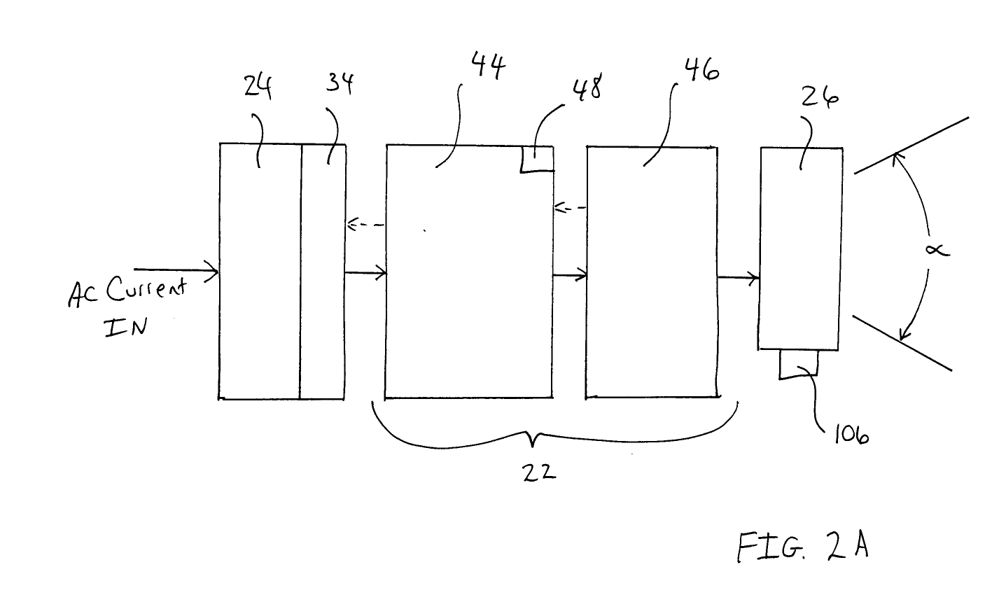

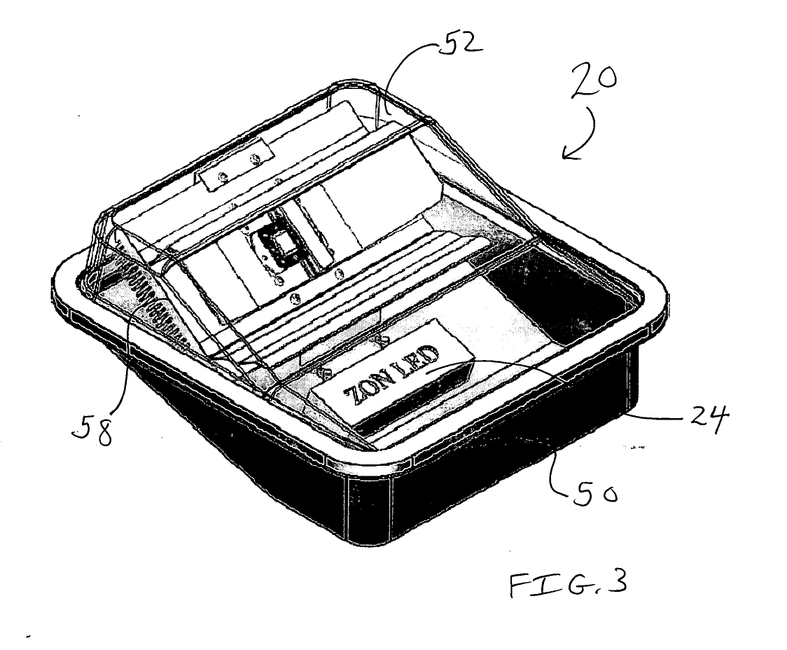

FIGS. 3 and 4 illustrate an embodiment of a fully assembled device 20. As best seen in FIG. 4, the device 20 includes the control system 22, the LED assembly 26, a housing 50, a light cover 52, a pair of mounting brackets 54, at least one reflector 56, and a heat sink 58. Each reflector 56 includes a reflective surface 60. The LED assembly 26 is thermally coupled to the heat sink 58 for transmitting heat generated by the LED assembly 26 to the heat sink 58. The reflectors 56 may be angled to direct light emitted from the LED assembly 26 toward a desired area within a focus of angle α (FIG. 2A).

In the embodiment illustrated, the light cover is constructed of one or more flat panels of polycarbonate (such as Opticarb 1614UR) where the panels are of a constant thickness and the surfaces are as flat as practical. Further, in some embodiments, the reflectors are manufactured by a vapor deposited aluminum, where the reflector is constructed of aluminum and a small portion of aluminum is vaporized and deposited on the reflective surfaces 60 of the reflectors 56. The surfaces 60 may then be polished.

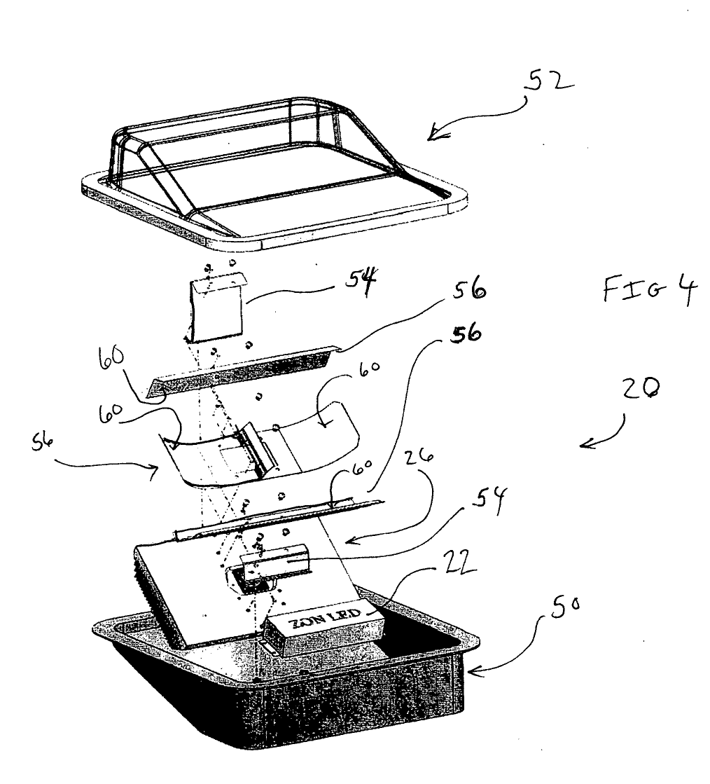

As best seen in FIGS. 5 and 6, the heat sink 58 includes a generally planar body 62 with a plurality of fins 64 extending therefrom. In the embodiment illustrated, the body 62 has a recess 66 formed therein defining a LED mounting surface 68. In an embodiment, the recess 66 may also include a plurality of mounting apertures 70.

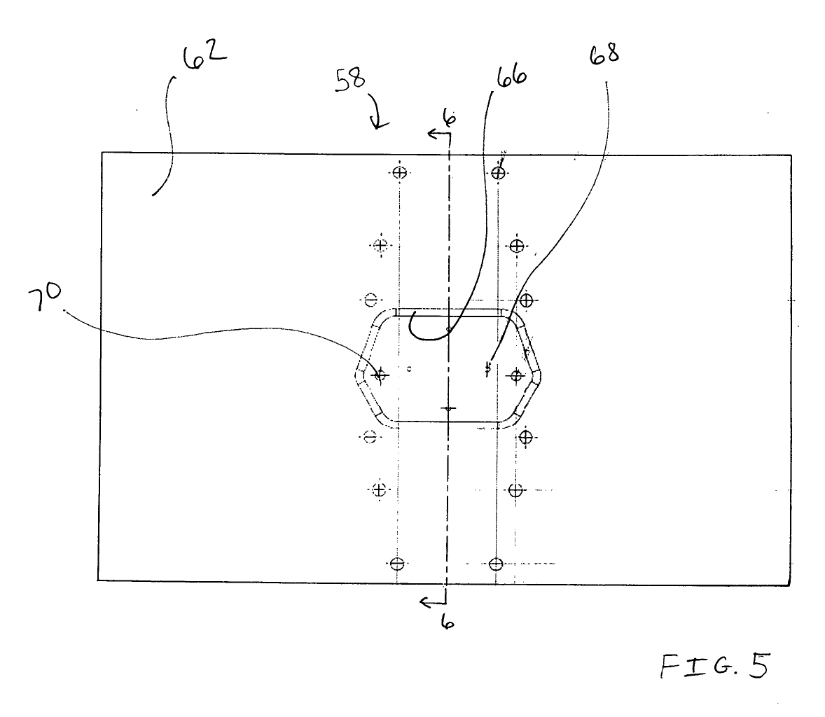

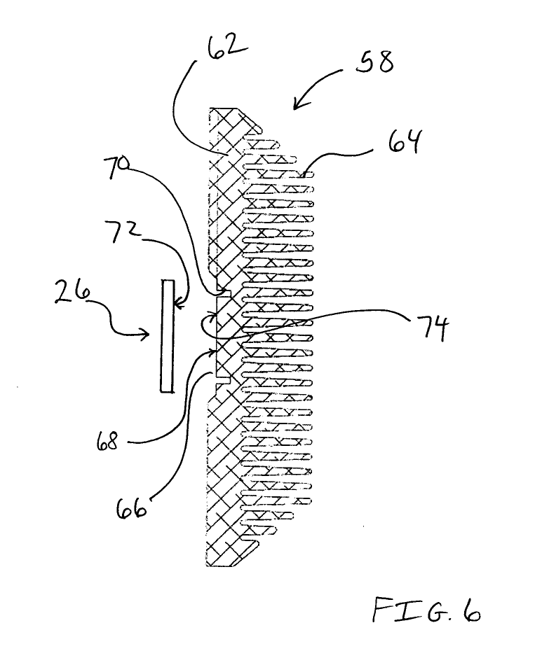

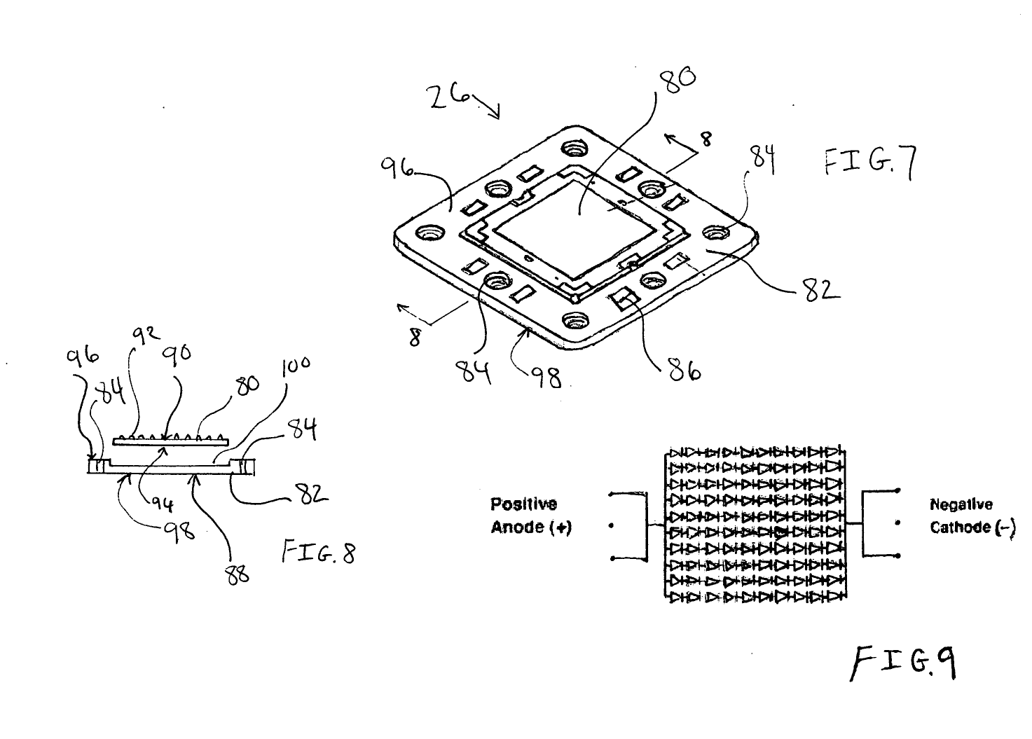

FIGS. 7-9 illustrate the LED assembly 26 includes a LED element 80 and a LED substrate 82. The substrate 82 may include a plurality of mounting apertures 84 for securing the LED assembly 26 to the heat sink 58. In the embodiment illustrated, the LED assembly 26 also includes a temperature sensor 86 coupled thereto for detecting the temperature of the LED assembly 26, as discussed in greater detail below. The LED substrate 82 includes a heat dissipation surface 88 for transferring heat to the heat sink 58. The LED element 80 includes a first surface 90 having a plurality of LED modules 92, and an opposing surface 94. Each LED module 92 includes an anode and a cathode configured as generally shown in FIG. 9. The substrate 82 is generally planar and defined by a first side 96 and a second side 98. The first side 96 may have a recess 100 proportioned such that the LED element 80 may fit tightly therein so as to ensure additional heat transfer from the LED element 80 to the substrate 82. The LED modules 92 extending from the first side 96 of the substrate 82. The second side 98 defines a heat dissipation surface that contours the LED mounting surface 68 of the heat sink 58. The opposing surface 94 of the LED element 80 is coupled to the recess 100.

In other embodiments, each LED module 92 may include a phosphor coating to provide a white light. The phosphor coating may be excited by the LED light output and to output light in response. Further, the LED modules 92 may be supplied with power through pulse width modulation such that the LED modules 92 may intermittently cease outputting light while the phosphor continues to output light resulting in a continuous output of light, such as is described in U.S. Pat. No. 6,028,694.

As best seen in the exploded view of FIG. 6, in the embodiment illustrated, the heat dissipation surface 88 of the LED assembly 26 has an adhesive 72 applied thereon and the LED mounting surface 68 of the heat sink 58 has an adhesive 74 applied thereon. When the LED assembly 26 is coupled to the heat sink 58, the adhesive may ensure that at least a portion of the heat generated by the LED assembly 26 is transferred to the heat sink 58 while providing sufficient coupling therebetween. In the embodiments illustrated, the adhesives are high temperature carbon based (carbon, diamond, diamonoid) pastes such as is disclosed in U.S. Pat. No. 5,026,748. In some embodiments, the paste may include greater than 50% carbon, while in other embodiments, the paste may include greater than 97% carbon. Further, in one embodiment, the paste provides a thermal conductivity of greater than 3.0 Watts per meter per degree Kelvin (W/mK).

In the embodiment illustrated, the control system 22 may have the capability to increase the LED brightness through a pulse width modulation (PWM) system that may increase the current to the LED assembly 26 (above the recommended maximum current) with pulses of higher amperage current at about 100 Hz or more. The AC input protection 30 may include a fuse and a fuse monitor operatively coupled to an indicator (such as a light) to indicate whether or not AC voltage input is present (Green color) and may also indicate if the fuse has blown (yellow color). The switching power supply or LED driver 32 may convert the main AC voltage from the AC input protection 30 and reduce the input voltage to a lower voltage suitable for the LED assembly 26 and may also regulate the current supplied to the LED assembly 26. The PWM brightness control 36 may regulate the pulse of width for the current give to the LED, for example on the order of about 100 Hz or more. The power and PWM driver 38 may control, support and drive the total brightness for the LED. Power monitor 40 will constantly monitor if there is any power coming from the power supply and provide an appropriate output. In the embodiment illustrated, the LED assembly 26 is manufactured by Edison Optoelectronics® supplying 4200 lumen (lm) in a 50 W (Watts) configuration and 7500 lm in a 100 W configuration. These characteristics may be only for a Neutral white light. Edison model numbers were ENSW-05-0707EB and ENSW-10-1010-EE for the 50 and the 100 W products, respectively.

One of the inventive concepts of the LED lighting module 1) is the incorporation of a Pulse Width Modulation (PWM) system that will increase the brightness for the LED light output. In one embodiment, increasing the width of the pulse applying through a Mosfet transistor or Hexfet transistor, the current available will flow through the transistors at a frequency of about 100 Hz or more depending of the brightness by controlling the time of ON and OFF on transistors. In one embodiment, the absolute maximum current for a 50 W LED assembly 26 is 2.4 Amps (A) and absolute maximum current for a 100 W LED assembly 26 is 3 A, but the amperage may be increased to 5 A by pulsing to < or = to 100 us which is equal or less than 10 KHz with a duty cycle of 25%. Therefore if a brighter light is desired, the time ON will be larger than OFF time and for a dimmer light the time OFF will be larger than ON time.

In some embodiments, a potentiometer may be instead of a PWM controller adjustably increase and decrease the light output of the LED assembly 26. The potentiometer may be adjusted by a radiofrequency (RF) controlled unit with a remote control to decrease or increase the light output from the LED assembly 26.

In an embodiment, the power supply or LED driver 38 may have an IP rated at 65 which is sufficient for outdoors with a temperature work from −30° C. to +50° C. Cables interconnecting the components may be rated for 125° C. at 300V and connections are sealed with an IP of 65. This allows the device 20 to operate either indoors or outdoors.

The LED assembly 26 may include a status indication device which monitors the operation of the power supply and the heat sink 58. The LED status device has two LED indicators which illuminate when the monitored supportive devices are operational. The supportive devices could include, but are not limited to a power supply and active heat sink 58 device. The LED operational status indicator device provides visual feedback as to the health of the LED assembly through monitoring two critical sub assemblies of the LED assembly, being the power supply and the active heat sink 42) device.

The device 20 may include a fan 106 (FIG. 2) to direct air across the fins 64. That is, the heat sink 58 may be transformed from a passive heat sink to an active heat sink with the inclusion of the fan 106. The control system 22 may include a fan control portion 108 to vary the current supplied to the fan 106 thereby controlling the amount of cooling of the fins 64. The control system 106 may be controlled via a remote control 110. The remote control 100 may control a single, or a plurality of devices 20. In the embodiment illustrated, the remote control 110 is an infrared (IR) remote in selective communication with the control system 22.

As shown in FIG. 9, the LED assembly 26 is in electrical communication with a positive anode (+) and a negative anode (−) where each of the individual LEDs are supplied with electrical energy.

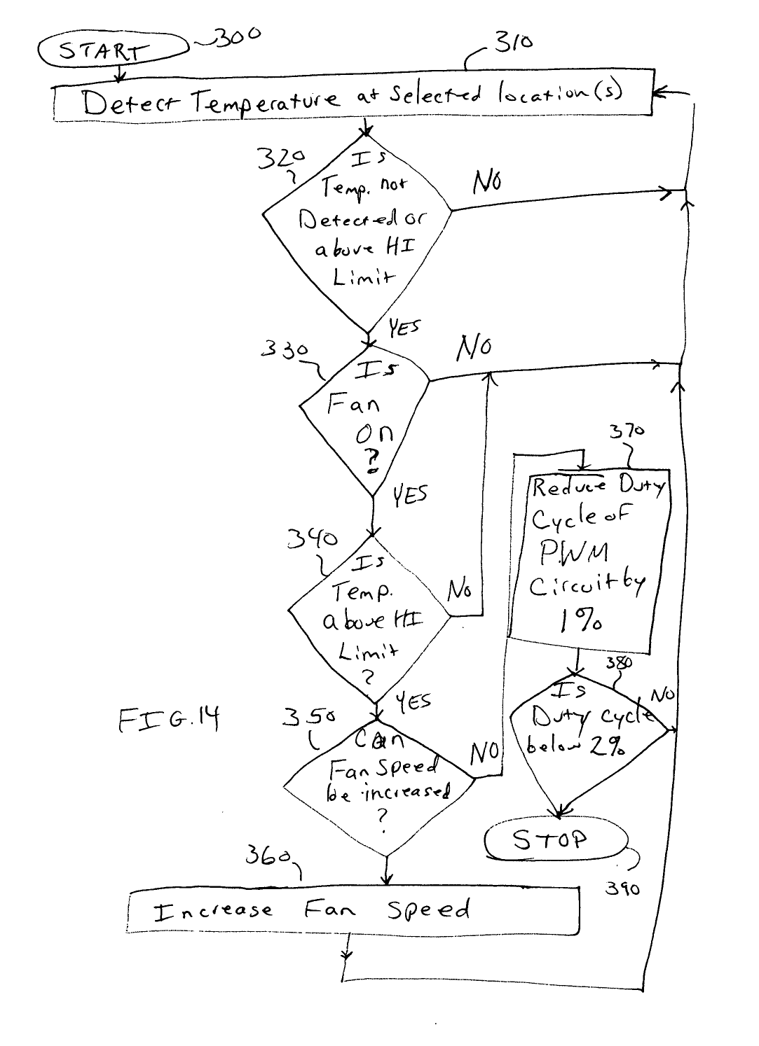

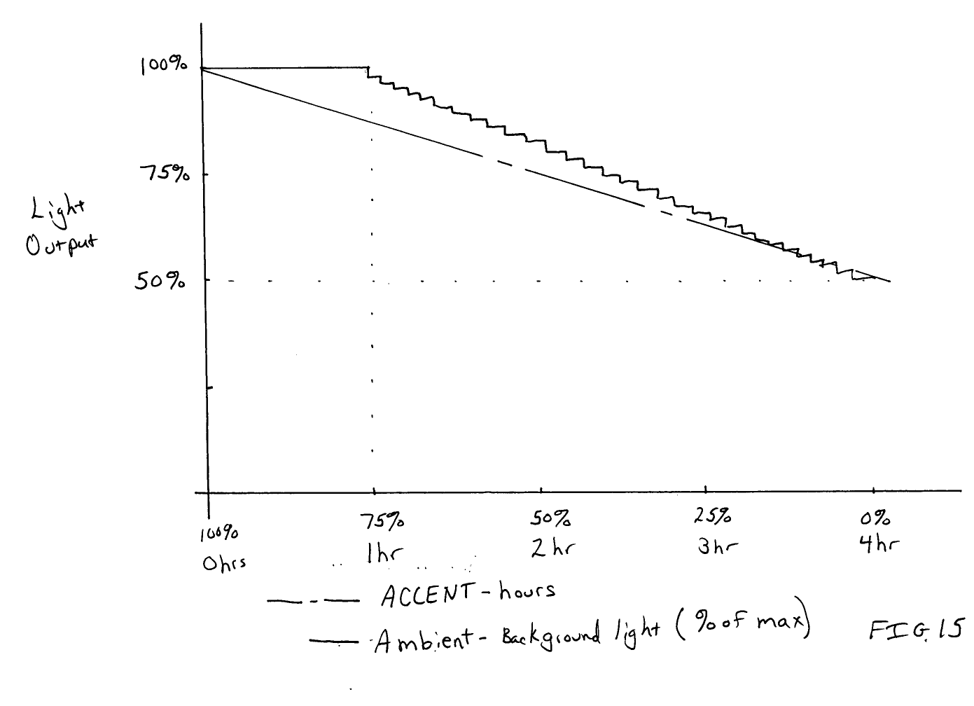

FIGS. 13 and 14 illustrate operational diagrams of the temperature control module 46. Referring back to FIG. 2, the temperature control module 46 is in communication with the temperature sensor 86 (FIG. 7). A HI limit for the temperature of the LED assembly 26 is selected based upon a desired temperature not to exceed.

The logic of FIG. 13 begins in step 200 and proceeds to step 210. In step 210, the temperature of the LED assembly 26 is detected by the temperature sensor 86, and the logic proceeds to step 220. In step 220, a determination is made as to whether the detected temperature is above the preselected HI temperature limit. If the determination in step 220 is negative, the logic returns to step 210. If the determination in step 220 is positive, the logic proceeds to step 230. In step 230, the duty cycle of the power source 24 is reduced by 1% or any other selected amount, and the logic proceeds to step 240. In step 240, a determination is made as to whether the duty cycle output by the PWM driver 34 is below 34. If the determination in step 240 is negative, the logic returns to step 210. If the determination in step 240 is positive, the logic proceeds to step 250. In step 250, the led assembly 26 is shut down, and the logic proceeds to step 260. [Steps 240 and 250 may be omitted since, in their absence, the light will essentially shut off.]

The logic of FIG. 14 begins in step 300 and proceeds to step 310. In step 310, the temperature of the LED assembly 36 is detected by the temperature sensor 86, and the logic proceeds to step 320. In step 320, a determination is made as to whether the detected temperature is above the preselected HI temperature limit. If the determination in step 320 is negative, the logic returns to step 310. If the determination in step 320 is positive, the logic proceeds to step 330. In step 330, a determination is made as to whether the fan 106 (FIG. 2 or 2A) is operating. If the determination in step 330 is negative, the logic returns to step 310. If the determination in step 330 is positive, the logic proceeds to step 340. In step 340, a determination is made as to whether the detected temperature is above the preselected HI temperature limit. If the determination in step 340 is negative, the logic returns to step 310. If the determination in step 340 is positive, the logic proceeds to step 350. In step 350, a determination is made as to whether the fan speed can be increased. If the determination in step 350 is negative, the logic proceeds to step 370. If the determination in step 350 is positive, the logic proceeds to step 360. In step 360 the fan speed is increased. This increase in fan speed may be a preselected percentage or to a higher speed level. In step 370, the duty cycle of the power source 34 is reduced by 1% or any other selected amount, and the logic proceeds to step 380. In step 380, a determination is made as to whether the duty cycle output by the PWM driver 34 is below 2%. If the determination in step 380 is negative, the logic returns to step 310. If the determination in step 380 is positive, the logic proceeds to step 390. In step 390, the led assembly 36 is shut down.

Also with reference back to FIG. 2A, the first control module 44 includes the first sensor 48 which is an optical sensor 48. The optical sensor 48 detects the background light (in lumens or other units, as a percentage of maximum) to control operation of the first control module 44.

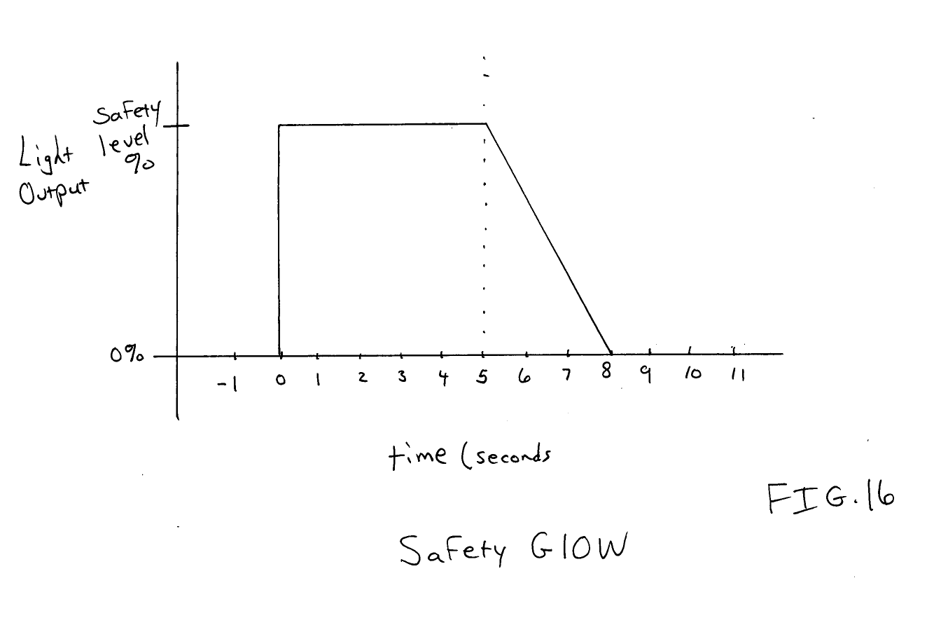

FIG. 15 illustrates an embodiment of the uses of the control of the duty cycle of the PWM driver 34. In one use, identified as “Ambient” or Ambient Glow, the first control module 44 detects the output of the optical sensor 48. When the optical sensor 48 detects the beginning of a dusk condition [just prior to nighttime where the ambient light from the sun reduces over several hours], the first control module begins a 4 hour clock to reduce the light output by the device 20 from the level when initiated (identified as 100%) to about one-half of the light output by the device 20 from the level when initiated (identified as 50%). As illustrated, the light output reduces linearly during the 4 hour timeframe.

FIG. 15 also illustrates an embodiment of a use of the first control system 44 identified as “Accent” or Accent Glow, where the optical sensor 48 detects the ambient light from the sun or other sources and produces an output (measured in lumens or other similar units) that maintains the light output at a level that is higher than the ambient light. That is, the when the ambient light is between 75 and 100% of a determined level, the amount of light output by the device 20 is at about 100%. Also in this embodiment, as the ambient light reduces between 75% and 0% of the determined level, the light output by the device 20 is reduced (either linearly of by steps, as illustrated) between 100% and 50% to ensure that the light output is higher than the ambient lighting.

Importantly, an array more than one of the devices 20 may be provided for a desired area (such as a warehouse, gas station, or billboard) where the devices 20 are controlled independently. Accordingly, the devices 20 that are closer to sources of light within the area (such as windows in a warehouse during a sunny day) may emit less light than the devices 20 that are farther from the sources of light. Therefore, the array of devices 20 may use less power to adequately light the desired area since the devices may be independently controlled, resulting in less unnecessary light output. That is, a conventional lighting array may include light devices that emit about the same amount of light in an area regardless of the ambient light of the area immediately surrounding an individual device (such as incandescent bulbs on the same parallel circuit), which may require more power to light the area than the devices described herein.

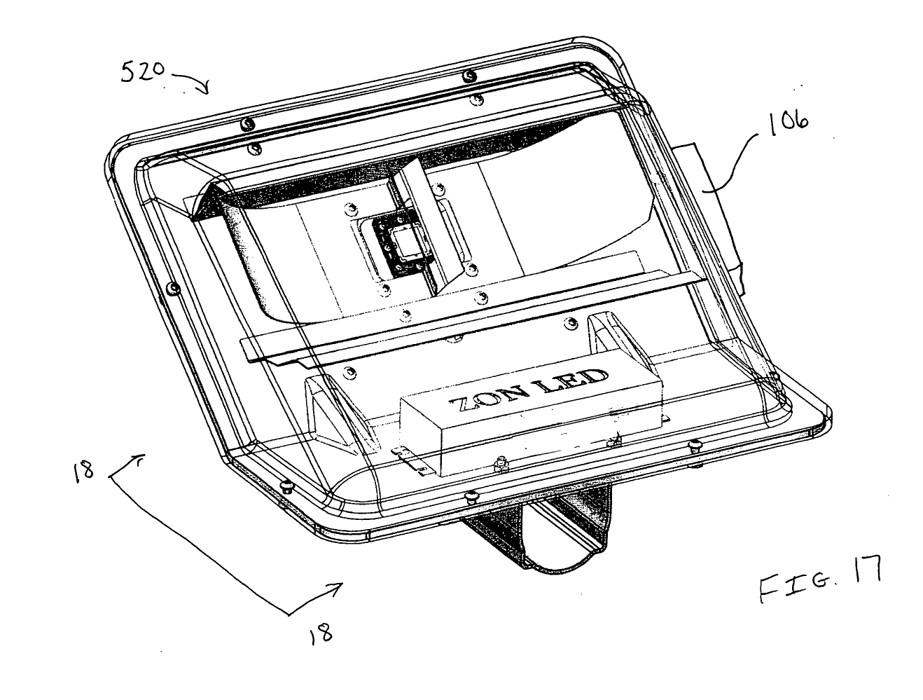

FIG. 16 illustrates an embodiment of a use of the control system 22 of FIG. 2A where the sensor 48 is a motion sensor. In this embodiment, the motion sensor detects movement within a preselected area near the device 20. When motion is detected, the device 20 is illuminated to a selected safety level and maintained at this safety level for a first preselected amount of time (in this embodiment, 5 seconds). Once the first preselected amount of time has expired, the device 20 is dimmed gradually over a second preselected amount of time (in this embodiment, 3 seconds). If motion is detected during either the first preselected amount of time or the second preselected amount of time, then the motion sensor causes the logic to reset and the first preselected amount of time begins anew resulting in light output while a user is in the area of device 20.

An array of devices employing the Safety Glow logic described in reference to FIG. 16 may use less energy when compared to conventional motion sensing control schemes. That is, since the individual devices 20 in an array of devices 20 (such as an array of devices in a warehouse) are controlled individually, the devices 20 turn on and off only when a user is in the immediate vicinity. In contrast, a conventional lighting array may be controlled by a single circuit (such as incandescent bulbs on the same parallel circuit) may include light devices that emit about the same amount of light in their area when a motion sensing device is activated in the area of all lights.

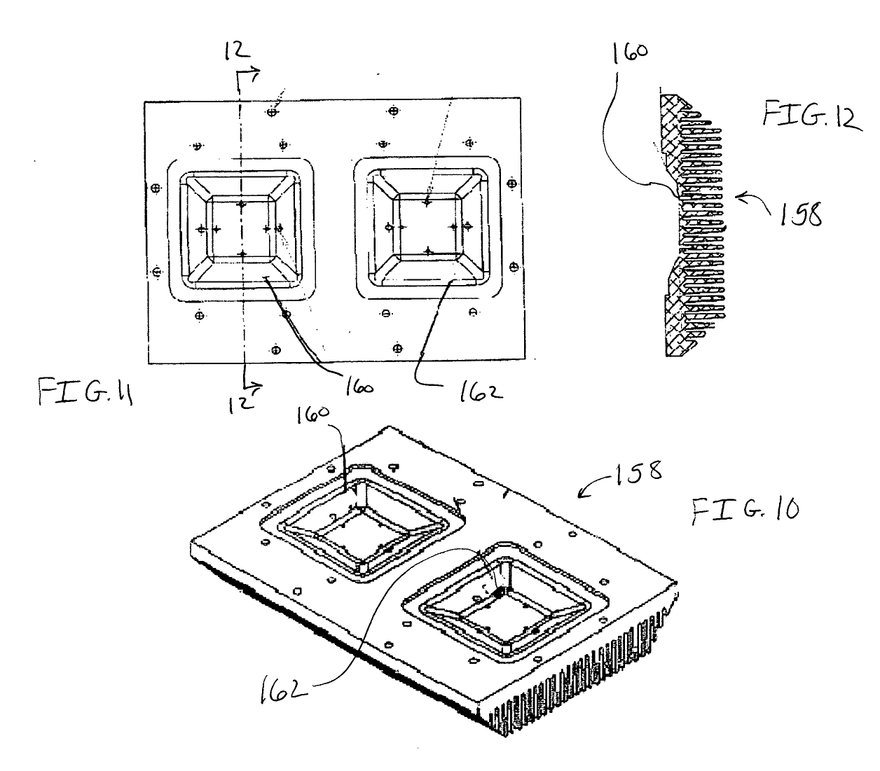

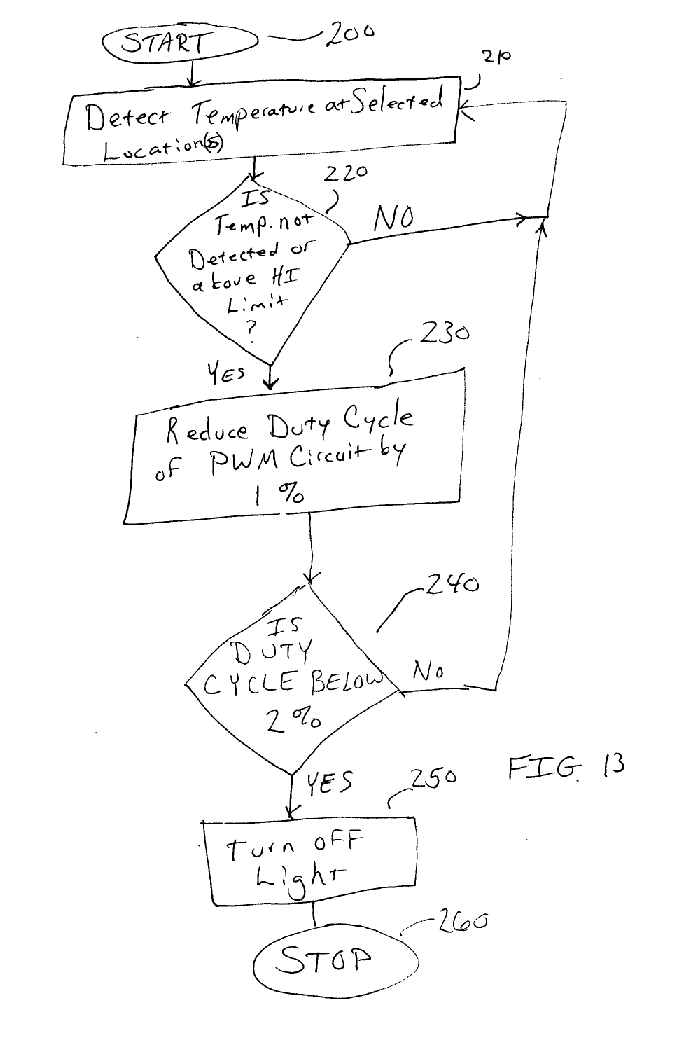

Alternatively, the LED assembly 26 may include a plurality of LED assemblies as illustrated in FIGS. 10-12 attached to a heat sink 158. The embodiment shown in FIGS. 10-12 represents a two light LED high bay housing. The heat sink 158 includes a first LED location 160 for a first LED assembly (not shown), and a second LED location 162 for a second LED assembly (not shown). In the embodiment illustrated, the first LED assembly and the second LED assembly are identical to the LED assembly 26, thereby providing an LED lighting module that will output about twice the output of the device 20.

The control system 22 may eliminate the need for a transformer and starting circuit usually integral to traditional High Bay Lighting fixtures. In the embodiment of the 50 W device, the heat sink 58 has between 4000 and 4500 square centimeters of surface area and the 100 W device has about 20,000 square centimeters of surface area.

The heat sink 58 may use the Peltier effect to create a heat flux between the junction of the LED assembly and the attached passive finned heat sink 58. The Peltier thermoelectric heat pump is a solid-state active heat pump, which transfers heat from one side of the LED substrate to the other side of the high bay fixture housing against the temperature gradient with consumption of electrical energy. The effectiveness of the pump at moving the heat away from the LED assembly is completely dependent upon the amount of current provided and the efficient heat dissipation of the attached housing. The thermoelectric approach provides instant, direct cooling as needed through direct feedback from a temperature sensor attached to the LED heat transfer plate.

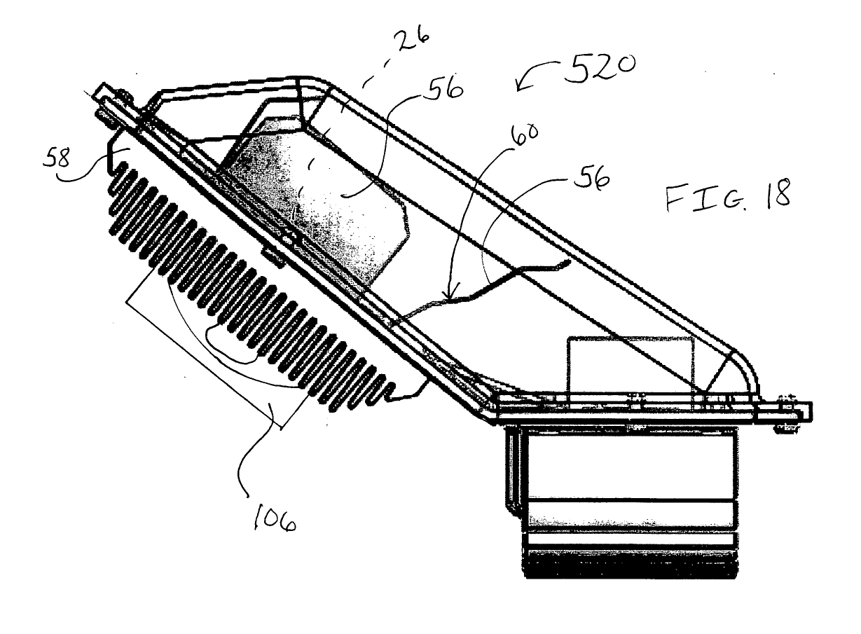

FIGS. 17 and 18 illustrate an embodiment of the device 20 as a device 520. The internal components of the device 520 are identical to the device 20 (the control system 22, the LED assembly 26, the mounting brackets 54, the at least one reflector 56, and the heat sink 58) and the device 520 may also include the fan 106 for directing air across tins of the heat sink 58. The angles of the reflectors 56 are configured for directing the light to a desired area, such as a billboard, while not directing light to areas beyond the billboard.

Although the steps of the method of assembling the device 20 may be listed in an order, the steps may be performed in differing orders or combined such that one operation may perform multiple steps. Furthermore, a step or steps may be initiated before another step or steps are completed, or a step or steps may be initiated and completed after initiation and before completion of (during the performance of) other steps.

The preceding description has been presented only to illustrate and describe exemplary embodiments of the methods and systems of the present invention. It is not intended to be exhaustive or to limit the invention to any precise form disclosed. It will be understood by those skilled in the art that various changes may be made and equivalents may be substituted for elements thereof without departing from the scope of the invention. In addition, many modifications may be made to adapt a particular situation or material to the teachings of the invention without departing from the essential scope. Therefore, it is intended that the invention not be limited to the particular embodiment disclosed as the best mode contemplated for carrying out this invention, but that the invention will include all embodiments falling within the scope of the claims. The invention may be practiced otherwise than is specifically explained and illustrated without departing from its spirit or scope. The scope of the invention is limited solely by the following claims.

What is claimed is:

1. An illumination apparatus, comprising:
a LED assembly having a plurality of LED modules and a substrate, wherein each LED module includes an anode and a cathode, wherein the substrate is generally planar and defined by a first side and a second side with the LED modules extending from the first side, wherein the second side is defined by a heat dissipation surface, and wherein the first side is opposite the second side;
a heat sink having a plurality of fins for heat dissipation, wherein a heat input surface portion of the heat sink is bonded to the heat dissipation surface of the LED assembly; and
a control system for supplying electrical energy to the LED assembly, wherein the electrical energy is pulse width modulated.

2. The apparatus of claim 1, wherein the heat sink is bonded to the heat dissipation surface of the LED assembly with an adhesive containing at least 97 percent carbon.

3. The apparatus of claim 1, further comprising a temperature sensor for detecting a parameter indicative of temperature of a portion of the apparatus.

4. The apparatus of claim 3, wherein the control system selectively reduces the power to the LED assembly in response to a change in temperature.

5. The apparatus of claim 4, wherein the temperature sensor is directly coupled to the LED assembly.

6. The apparatus of claim 1, wherein each LED module includes a phosphor film for emitting light.

7. The apparatus of claim 1, further comprising a fan for directing air across the fins of the heat sink.

8. The apparatus of claim 1, further comprising a plurality of reflectors for directing light emitted by the LED assembly.

9. The apparatus of claim 8, further comprising a clear, polycarbonate lens cover with a generally uniform thickness for permitting the light to pass therethrough.

10. A method, comprising:
removing a protective portion from a heat dissipation surface of a substrate, wherein the substrate is generally planar and defined by a first side and a second side with a plurality of LED modules extending from the first side, wherein the second side is defined by the heat dissipation surface, and wherein the first side is opposite the second side;
applying a first thermally conductive adhesive to at least a portion of the heat dissipation surface;
applying a second thermally conductive adhesive to at least a portion of a heat sink having a plurality of fins for heat dissipation, wherein a heat input surface portion of the heat sink is bonded to the heat dissipation surface of the LED assembly;
coupling a power source for supplying electrical energy to the LED assembly, wherein the electrical energy is pulse width modulated; and
coupling a control system to the power source for controlling the power source.

11. The method of claim 10. wherein the first thermally conductive adhesive includes at least 97 percent carbon.

12. The method of claim 10, further comprising providing a continuous output of light from the LED assembly.

13. The method of claim 10, further comprising coupling a heat sensor directly to the LED assembly.

14. The method of claim 10, further comprising detecting a parameter indicative of temperature of the LED assembly.

15. The method of claim 14, further comprising reducing the light output of the LED modules in response a detected temperature that is above a preselected limit.

16. The method of claim 10, further comprising reflecting the light with a reflector constructed of vapor deposited aluminum.
